(19) United States
(12) Patent Application Publication
(10) Pub. No.: US 2023/0378206 A1
(43) Pub. Date: Nov. 23, 2023

(54) IMAGE SENSOR

(71) Applicant: SAMSUNG ELECTRONICS CO., LTD., Suwon-si (KR)

(72) Inventors: Ji Su PARK, Suwon-si (KR); Seung Joo NAH, Suwon-si (KR); Hoe Min JEONG, Suwon-si (KR); Hee Geun JEONG, Suwon-si (KR)

(73) Assignee: SAMSUNG ELECTRONICS CO., LTD., Suwon-si (KR)

(21) Appl. No.: 18/124,973

(22) Filed: Mar. 22, 2023

(30) Foreign Application Priority Data
May 17, 2022 (KR) 10-2022-0060152
Aug. 11, 2022 (KR) 10-2022-0100309
Mar. 7, 2023 (KR) 10-2023-0029846

(51) Int. Cl. H01L 27/146

(52) U.S. Cl. CPC H01L 27/14623; H01L 27/1462; H01L 27/14645

(57) ABSTRACT

Disclosed is an image sensor including a substrate having a photoelectric conversion element disposed therein a passivation layer disposed on the substrate and extending in a first direction, a conductive pattern disposed on the passivation layer, and an adhesive layer deposited on the passivation layer and the conductive pattern, wherein the conductive pattern includes a first flat area disposed on the passivation layer and extending in the first direction, and an inclined area connected to the first flat area, wherein a first top face of the inclined area is bent from a second top face of the first flat area, wherein the first top face has a constant slope with respect to the second top face.

### CROSS-REFERENCE TO RELATED APPLICATION

This application based on and claims priority under 35 U.S.C. 119 from Korean Patent Application No. 10-2022-0060152 filed on May 17, 2022, No. 10-2022-0100309 filed on Aug. 11, 2022 and No. 10-2023-0029846 filed on Mar. 7, 2023 in the Korean Intellectual Property Office, the disclosures of which are incorporated by reference herein in their entireties.

### BACKGROUND

### Field

The disclosure relates to an image sensor.

### Description of Related Art

An image sensor is a semiconductor element that converts optical information into an electrical signal. The image sensor may include a Charge Coupled Device (CCD0 based image sensor and a Complementary Metal-Oxide Semiconductor (CMOS) based image sensor.

The image sensor may be provided in a package having a structure that protects the image sensor and, at the same time, allows light to be incident on a light receiving surface or a sensing area of the image sensor.

### SUMMARY

According to an aspect of the disclosure, there is provided an image sensor in which a conductive pattern is etched in an inclined manner to improve a step coverage of a material deposited on the conductive pattern.

According to some aspects of the present inventive concept, there is provided an image sensor comprising a substrate having a photoelectric conversion element disposed therein, a passivation layer disposed on the substrate and extending in a first direction, a conductive pattern disposed on the passivation layer and an adhesive layer deposited on the passivation layer and the conductive pattern, wherein the conductive pattern includes a first flat area disposed on the passivation layer and extending in the first direction and an inclined area connected to the first flat area, wherein a first top face of the inclined area is bent from a second top face of the first flat area, wherein the first top face has a constant slope with respect to the second top face.

According to some aspects of the present inventive concept, there is provided an image sensor comprising a substrate having a photoelectric conversion element disposed therein, a passivation layer disposed on the substrate and extending in a first direction, a conductive pattern formed on the passivation layer and an adhesive layer formed along the conductive pattern and formed on the passivation layer, wherein the conductive pattern includes a first flat area extending from the passivation layer in a second direction perpendicular to the first direction and extending so as to have a first constant thickness, an inclined area, wherein a thickness of the conductive pattern in the inclined area from the passivation layer in the second direction decreases from the first thickness as the conductive pattern in the inclined area extends away from the first flat area in the first direction.

According to some aspects of the present inventive concept, there is provided an image sensor comprising a substrate, a passivation layer disposed on the substrate and extending in a first direction, a trench extending through the passivation layer and extending through a portion of the substrate, a conductive pattern extending along a profile of the trench and formed on the passivation layer, a pad disposed in the trench and on the conductive pattern and an adhesive layer formed on the conductive pattern and the passivation layer, wherein the conductive pattern includes a first flat area disposed on the passivation layer and extending in the first direction and an inclined area connected to the first flat area, wherein a top face of the conductive pattern in the inclined area is inclined at a first slope of a first angle relative to a top face of the passivation layer, wherein the first angle is greater than 0 degree and smaller than 90 degrees, wherein a top face of the conductive pattern in the inclined area is flat.

However, the disclosure is not limited thereto, and as such, other purposes and advantages that are not mentioned may be understood based on following descriptions, and may be more clearly understood based on embodiments according to the disclosure.

Specific details of other embodiments are included in detailed descriptions and drawings.

### BRIEF DESCRIPTION OF DRAWINGS

The above and other aspects and features of the disclosure will become more apparent by describing in detail illustrative embodiments thereof with reference to the attached drawings, in which:

FIG. 1 is a block diagram of an image sensor according to an example embodiment of the disclosure.

FIG. 2 is an illustrative circuit diagram of a unit pixel area of an image sensor according to an example embodiment of the disclosure.

FIG. 3 is a schematic plan view of an image sensor according to an example embodiment of the disclosure.

FIG. 4 is a cross-sectional view taken along lines A-A′ and B-B′ in FIG. 3.

FIG. 5 is an enlarged view of the R1 area of FIG. 4.

FIG. 6 is a diagram for illustrating an image sensor according to another embodiment of the present disclosure.

FIG. 7 is a cross-sectional view taken along lines A-A′ and C-C′ in FIG. 3.

FIG. 8 is an enlarged view of the R2 area of FIG. 7.

FIG. 9 is an enlarged view of the R3 area of FIG. 7.

FIG. 10 is a cross-sectional view taken along lines A-A′ and D-D′ in FIG. 3.

FIG. 11 is an enlarged view of the R4 area of FIG. 10.

### DETAILED DESCRIPTIONS

Hereinafter, embodiments of the disclosure will be described in detail and clearly to such an extent that one skilled in the art easily carries out the disclosure. In the following description, specific details such as detailed components and structures are merely provided to assist the overall understanding of embodiments of the disclosure. For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the disclosure, numerous specific details are set forth in order to provide a thorough understanding of the disclosure. However, it will be understood that the disclosure may be practiced without these specific details. In other instances, well-known methods, procedures, components, and circuits have not been described in detail so as not to unnecessarily obscure aspects of the disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the disclosure as defined by the appended claims.

In the example embodiments illustrated in the drawings, the characteristics of the elements, such as shapes, sizes, ratios, angles, numbers etc, are illustrative, and the disclosure is not limited thereto. The same reference numerals refer to the same elements herein. Further, descriptions and details of well-known steps and elements are omitted for simplicity of the description. Furthermore, in the following detailed description of the disclosure, numerous specific details are set forth in order to provide a thorough understanding of the disclosure. However, it will be understood that the disclosure may be practiced without these specific details. In other instances, well-known methods, procedures, components, and circuits have not been described in detail so as not to unnecessarily obscure aspects of the disclosure.

The terminology used herein is for the purpose of describing particular embodiments only and is not intended to limit the disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the disclosure.

In addition, it will also be understood that when a first element or layer is referred to as being present “on” or “beneath” a second element or layer, the first element may be provided directly on or beneath the second element or may be provided indirectly on or beneath the second element with a third element or layer being provided between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is provided “on” or “on a top” of another layer, film, region, plate, or the like, the former may directly contact the latter or still another layer, film, region, plate, or the like may be provided between the former and the latter. As used herein, when a layer, film, region, plate, or the like is directly provided “on” or “on a top” of another layer, film, region, plate, or the like, the former directly contacts the latter and still another layer, film, region, plate, or the like is not provided between the former and the latter. Further, as used herein, when a layer, film, region, plate, or the like is provided “below” or “under” another layer, film, region, plate, or the like, the former may directly contact the latter or still another layer, film, region, plate, or the like may be provided between the former and the latter. As used herein, when a layer, film, region, plate, or the like is directly provided “below” or “under” another layer, film, region, plate, or the like, the former directly contacts the latter and still another layer, film, region, plate, or the like is not provided between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of the disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings is turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

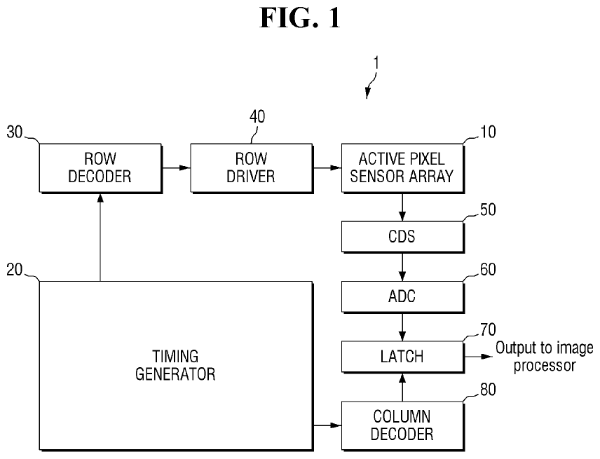

FIG. 1 is a block diagram of an image sensor according to an example embodiment of the disclosure.

Referring to FIG. 1, an image sensor 1 according to some embodiments of the present disclosure includes an active pixel sensor array 10, a timing generator 20, a row decoder 30, a row driver 40, a correlated double sampler (CDS) 50, an analog to digital converter (ADC) 60, a latch 70, and a column decoder 80.

The active pixel sensor array 10 includes a plurality of unit pixels respectively including photoelectric conversion elements and arranged two-dimensionally. The plurality of unit pixels may perform a function of converting an optical image into an electrical output signal.

The active pixel sensor array 10 may be driven upon receiving a plurality of drive signals, such as a row select signal, a reset signal, and a charge transfer signal, from the row driver 40. Further, the converted electrical output signal may be provided to the correlated double sampler 50 through a vertical signal line.

The timing generator 20 may provide a timing signal and a control signal to the row decoder 30 and the column decoder 80.

The row driver 40 may provide a plurality of drive signals for driving the plurality of unit pixels to the active pixel sensor array 10 based on a decoding result from the row decoder 30. In general, when the unit pixels are arranged in a matrix form, a drive signal may be provided on a row basis.

The correlated double sampler 50 may receive the output signal from the active pixel sensor array 10 through the vertical signal line, and hold and sample the received signal. That is, the CDS 50 may perform double-sampling on a specific noise level and a signal level of the output signal, and may output a difference level corresponding to a difference between the noise level and the signal level.

The analog-to-digital converter 60 may convert an analog signal corresponding to the difference level into a digital signal and output the digital signal.

The latch 70 may latch the digital signal, and may sequentially output the latched signal to an image signal processing unit (i.e., an image processor) based on a decoding result from the column decoder 80.

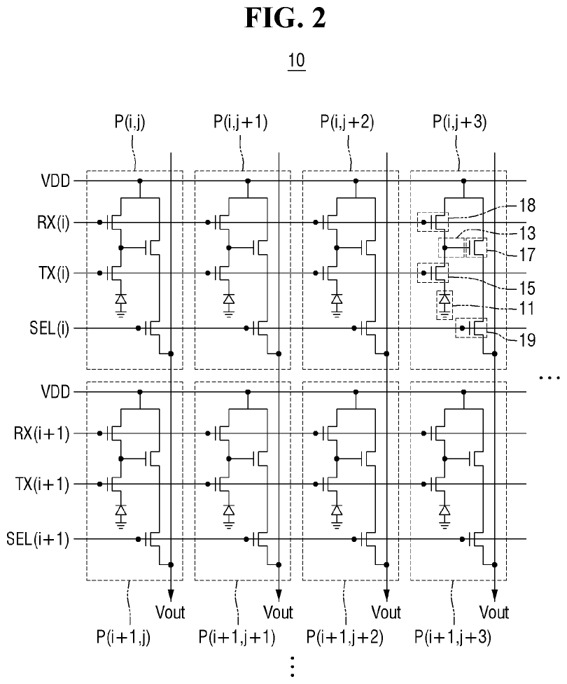

FIG. 2 is an illustrative circuit diagram of a unit pixel area of an image sensor according to an example embodiment of the disclosure.

Referring to FIG. 2, pixels P are arranged in a matrix column to constitute the active pixel sensor array 10. Each pixel P includes a photoelectric conversion element 11, a floating diffusion (FD) area 13, a charge transfer element 15, a drive element 17, a reset element 18, and a select element 19. Structures and functions of these elements may be described based on pixels P(i, j), P(i, j+1), P(i, j+2), P(i, j+3), . . . in an i-th row by way of example.

The photoelectric conversion element 11 may absorb incident light and accumulate a charge corresponding to an amount of the light. The photoelectric conversion element 11 may be embodied as a photodiode, a phototransistor, a photogate, a pinned photodiode, or a combination thereof. An example in which the photoelectric conversion element 11 is embodied as the photodiode is illustrated in the drawing.

The photoelectric conversion element 11 may be coupled to the charge transfer element 15 that transfers the accumulated charge to the FD area 13.

The FD area 13 refers to an area that converts the charge into voltage. For example, because the FD area has parasitic capacitance, the FD area accumulates the charges in the FD area.

According to an example embodiment, the drive element 17 may be a source follower amplifier, which may amplify change in an electrical potential of the FD area 13 upon receiving the charges accumulated in the photoelectric conversion element 11 and output the amplified change to an output line Vout.

According to an example embodiment, the reset element 18 may periodically reset the FD area 13. The reset element 18 may be embodied as one MOS transistor driven by a bias provided via a reset line RX(i) that applies a predefined bias (i.e., a reset signal).

When the reset element 18 is turned on based on the bias provided via the reset line RX(i), a predefined electrical potential (e.g., power supply voltage VDD) provided to a drain of the reset element 18 may be transferred to the FD area 13.

According to an example embodiment, the select element 19 may perform a function of selecting a pixel P to be read on a row basis. The select element 19 may be embodied as one MOS transistor driven by a bias (i.e., a row select signal) provided via a row select line SEL(i).

When the select element 19 is turned on based on the bias provided via the row select line SEL(i), a predefined electrical potential (e.g., supply voltage VDD) provided to a drain of the select element 19 may be delivered to a drain area of the drive element 17.

The transfer line TX(i) for applying the bias to the charge transfer element 15, the reset line RX (i) for applying the bias to the reset element 18, and the row select line SEL (i) for applying the bias to the select element 19 may extend in a substantially parallel manner to each other and in a row direction and may be arranged in a column direction.

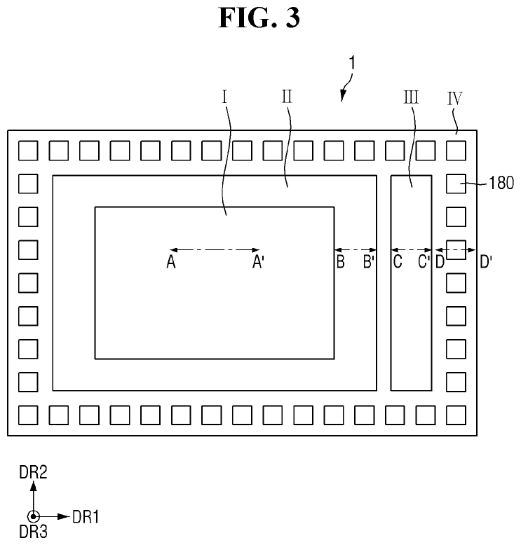

FIG. 3 is a schematic plan view of an image sensor according to an example embodiment of the disclosure.

Referring to FIG. 3, the image sensor 1 according to an example embodiment of the disclosure may include a first area I, a second area II, a third area III, and a fourth area IV.

According to an example embodiment, the first area I and the second area II may constitute a sensor array area. In a plane defined by a first direction DR1 and a second direction DR2 perpendicular to the first direction DR1, the second area II may surround the first area I.

The first area I may be an active pixel sensor area including an active pixel for generating an active signal corresponding to wavelengths of light from an outside. The second area II may be an optical black sensor area for blocking light from the outside to generate an optical black signal.

According to an example embodiment, the fourth area IV may be a pad area. A plurality of pads 180 provided in the fourth area IV may transmit and receive an electrical signal to and from an external device. In the plane defined by the first direction DR1 and the second direction DR2, the fourth area IV may surround the second area II.

According to an example embodiment, the third area III may be a connection area. The third area III may be electrically connected to a logic circuit area. The third area III may be provided between the second area II as the optical black sensor area and the fourth area IV as the pad area.

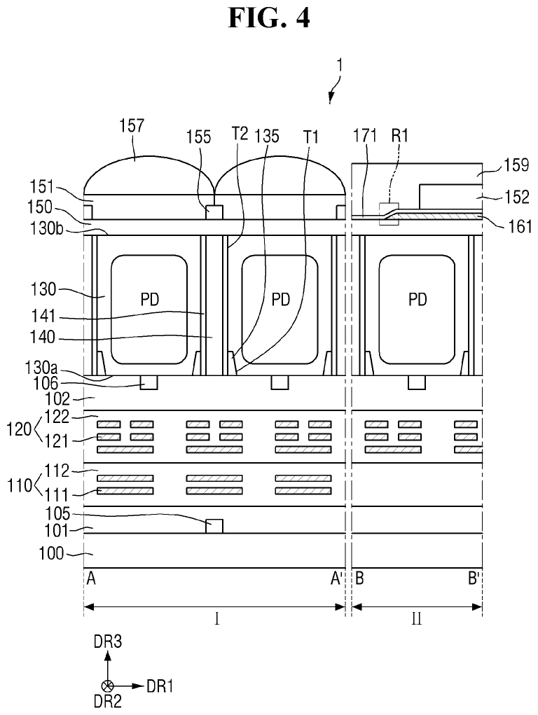

FIG. 4 is a cross-sectional view taken along lines A-A′ and B-B′ in FIG. 3.

Referring to FIG. 4, the image sensor 1 according to an example embodiment of the disclosure may include a first substrate 100, a first insulating layer 101, a second insulating layer 102, a first gate structure 105, a second gate structure 106, a first wiring structure 110, a second wiring structure 120, a second substrate 130, a photoelectric conversion element PD, a first element isolation layer 135, a second element isolation layer 140, a trench barrier layer 141, a passivation layer 150, a first color filter 151, a second color filter 152, a grid pattern 155, a micro lens 157, a transparent layer 159, a first conductive pattern 161, and an adhesive layer 171.

The first substrate 100 may be made of, for example, bulk silicon or an (SOI) silicon-on-insulator. The first substrate 100 may be embodied as a silicon substrate, or may include a material other than silicon. For example, the first substrate 100 may be made of silicon germanium, indium antimonide, lead telluride, indium arsenide, indium phosphide, gallium arsenide or gallium antimonide. Alternatively, the first substrate 100 may include a base substrate and an epitaxial layer formed on the base substrate.

The first insulating layer 101 may be provided on the first substrate 100. The first insulating layer 101 may be provided to cover the first gate structure 105 provided on the first substrate 100. The first insulating layer 101 may include, for example, at least one of silicon oxide (SiO₂), silicon nitride (SiN), silicon oxynitride (SiON), a low dielectric constant material, and combinations thereof.

The first wiring structure 110 may be provided on the first insulating layer 101. The first wiring structure 110 may include a first interlayer insulating film 112 and a plurality of first wiring layers 111 provided inside the first interlayer insulating film 112.

The first wiring layer 111 may include, for example, aluminum (Al), copper (Cu), tungsten (W), cobalt (Co), ruthenium (Ru), or the like. However, the disclosure is not limited thereto, and as such, according to another example embodiment, the first wiring layer 111 may include one or more other materials, or a combination of various materials.

The first interlayer insulating film 112 may include, for example, at least one of silicon oxide (SiO₂), silicon nitride (SiN), silicon oxynitride (SiON), a low dielectric constant material, or combinations thereof.

The second wiring structure 120 may be provided on the first wiring structure 110. The second wiring structure 120 may include a second interlayer insulating film 122 and a plurality of second wiring layers 121 provided inside the second interlayer insulating film 122.

The second wiring layer 121 may include, for example, aluminum (Al), copper (Cu), tungsten (W), cobalt (Co), ruthenium (Ru), or the like. However, the disclosure is not limited thereto, and as such, according to another example embodiment, the second wiring layer 121 may include one or more other materials, or a combination of various materials.

The second interlayer insulating film 122 may include, for example, at least one of silicon oxide (SiO₂), silicon nitride (SiN), silicon oxynitride (SiON), a low dielectric constant material, or combinations thereof.

The second insulating layer 102 may be provided on the second wiring structure 120. The second insulating layer 102 may be provided to cover a plurality of second gate structures 106 provided on a bottom face 103a of the second substrate 130. The second gate structure 106 may act as, for example, a gate of the charge transfer element, a gate of the reset element, or a gate of the drive element.

The second insulating layer 102 may include, for example, at least one of silicon oxide silicon oxide (SiO₂), silicon nitride (SiN), silicon oxynitride (SiON), a low dielectric constant material, or combinations thereof.

The second substrate 130 may be provided on the second insulating layer 102. The second substrate 130 may be made of, for example, bulk silicon or an (SOI) silicon-on-insulator. The second substrate 130 may be embodied as a silicon substrate, or may include a material other than silicon, for example, silicon germanium, indium antimonide, lead telluride, indium arsenide, indium phosphide, gallium arsenide or gallium antimonide. Alternatively, the second substrate 130 may include a base substrate and an epitaxial layer formed on the base substrate.

For convenience of description, an example in which the second substrate 130 includes the first area I as the active pixel sensor area is described.

The photoelectric conversion element PD may be provided in the second substrate 130. The photoelectric conversion element PD may be provided in the first area I and in the second substrate 130. Further, the photoelectric conversion element PD may be provided in the second area II and in the second substrate 130.

The photoelectric conversion element PD may be embodied as, for example, a photodiode. However, the disclosure is not limited thereto, and as such, according to another example embodiment, the photoelectric conversion element PD may be an element different from the photodiode. A plurality of photoelectric conversion elements PD may be provided in the second substrate 130. The photoelectric conversion elements PD may be isolated from each other via a first element isolation layer 135 and a second element isolation layer 140.

The first element isolation layer 135 may be provided in a first trench T1. A bottom face of the first element isolation layer 135 may be in contact with the second insulating layer 102.

The first element isolation layer 135 may include, for example, at least one of silicon oxide (SiO₂), silicon nitride (SiN), silicon carbide (SiC), silicon oxycarbide (SiOC), silicon oxynitride (SiON), and silicon oxycarbonitride (SiOCN).

A second trench T2 may be formed on the first trench T1 and between adjacent ones of the plurality of photoelectric conversion elements PD. The second trench T2 may extend from the bottom face 130a of the second substrate 130 into the second substrate 130 and in a third direction DR3. The second trench T2 may extend to a top face 130b of the second substrate 130. However, the disclosure is not limited thereto, and as such, according to another example embodiment, the first trench T1 and or the second trench T2 may have a different configuration or a different structure

A dimension in the first direction DR1 of the second trench T2 may be smaller than a dimension in the first direction DR1 of the first trench T1.

The second element isolation layer 140 may be provided in the second trench T2. The second element isolation layer 140 may include a material different from that of the first element isolation layer 135. The second element isolation layer 140 may include a material having excellent gap-fill performance, for example, polysilicon (poly-Si). However, the disclosure is not limited thereto, and as such, according to another example embodiment, the second element isolation layer 140 may include one or more other materials or a combination thereof.

A trench barrier layer 141 may be provided in the second trench T2 and along a sidewall of the second trench T2. Specifically, the trench barrier layer 141 may be provided in the second trench T2 and between a sidewall of the second element isolation layer 140 and the second substrate 130 and between the second element isolation layer 140 and the first element isolation layer 135. Although it is illustrated in FIG. 4 that the trench barrier layer 141 is conformally formed in the second trench T2, the disclosure is not limited thereto, and as such, according to another example embodiment, the trench barrier layer 141 may be formed in a different manner.

The trench barrier layer 141 may include the same material as that of the passivation layer 150, for example, a high dielectric constant insulating material. However, the disclosure is not limited thereto, and as such, according to another example embodiment, the trench barrier layer 141 may include a material different from that of the passivation layer 150.

The passivation layer 150 may be provided on the top face 130b of the second substrate 130. The passivation layer 150 may include, for example, a high dielectric constant insulating material. Further, the passivation layer 150 may include an amorphous crystal structure. More specifically, at least a portion of the high dielectric constant insulating material constituting the passivation layer 150 may have an amorphous crystal structure. However, the disclosure is not limited thereto, and as such, according to another example embodiment, the passivation layer 150 may have a different structure.

Although it is illustrated in FIG. 4 that the passivation layer 150 is embodied as one layer, the disclosure is not limited thereto, and as such, according to another example embodiment, the passivation layer 150 may further include a planarization layer and an anti-reflection layer. In this case, the planarization layer may include, for example, at least one of a silicon oxide-based material, a silicon nitride-based material, a resin, or a combination thereof. The anti-reflective layer may include a high dielectric constant material, for example, hafnium oxide (HfO₂). However, the spirit of the disclosure is not limited thereto.

The first color filter 151 may be provided on the first area I of the second substrate 130 as the active pixel sensor area. The first color filter 151 is not provided on the second area II of the second substrate 130 as the optical black sensor area.

The first color filter 151 may be provided on the passivation layer 150. Each first color filter 151 may be positioned in a corresponding manner to each unit pixel. For example, the first color filters 151 may be arranged two-dimensionally (for example, in a matrix manner) in a plane defined by the first direction DR1 and the second direction DR2.

The first color filter 151 may include a red color filter, a green color filter, or a blue color filter depending on a color of the unit pixel. Further, the first color filter 151 may include a yellow color filter, a magenta color filter, and a cyan color filter, and may further include a white color filter.

The grid pattern 155 may be formed in a grid shape and on the top face 130b of the second substrate 130 so as to surround each of the unit pixels. For example, the grid pattern 155 may be provided between the first color filters 151 and on the passivation layer 150. The grid pattern 155 may reflect the incident light obliquely incident on the second substrate 130 to provide a larger amount of the incident light to the photoelectric conversion element PD.

The micro lens 157 may be provided on the first area I of the second substrate 130 as the active pixel sensor area. The micro lens 157 is not provided on the second area II of the second substrate 130 as the optical black sensor area.

The micro lens 157 may be provided on the first color filter 151. The micro lens 157 may be provided in a corresponding manner to each unit pixel. For example, one micro lens 157 may be provided on one first color filter 151. However, the disclosure is not limited thereto, and as such, according to another example embodiment, the micro lens 157 may be arranged in a different manner. The micro lenses 157 may be arranged in a plane defined by the first direction DR1 and the second direction DR2 two-dimensionally (for example, in a matrix manner).

The micro lens 157 has a convex shape and may have a predefined radius of curvature. Accordingly, the micro lens 157 may focus the incident light on the photoelectric conversion element PD.

The micro lens 157 may include, for example, an organic material such as a photosensitive resin, or an inorganic material. However, the disclosure is not limited thereto, and as such, according to another example embodiment, the micro lens 157 may include c combination of materials

According to an example embodiment, a first conductive pattern 161 may be provided on the second area II of the second substrate 130 as the optical black sensor area. The first conductive pattern 161 may be provided on the passivation layer 150.

The first conductive pattern 161 may include a metal. For example, the first conductive pattern 161 may include at least one of titanium (Ti) or tungsten (W). However, the disclosure is not limited thereto, and as such, according to another example embodiment, the first conductive pattern 161 may include one or more other materials, or a combination thereof

In this regard, the first conductive pattern 161 is deposited on the passivation layer 150 and then subjected to an etching process. At this time, the first conductive pattern 161 may be etched in an inclined manner so as to have an inclined shape as in a first enlarged area R1.

Thus, a step coverage of the adhesive layer 171 formed on the first conductive pattern 161 may be improved.

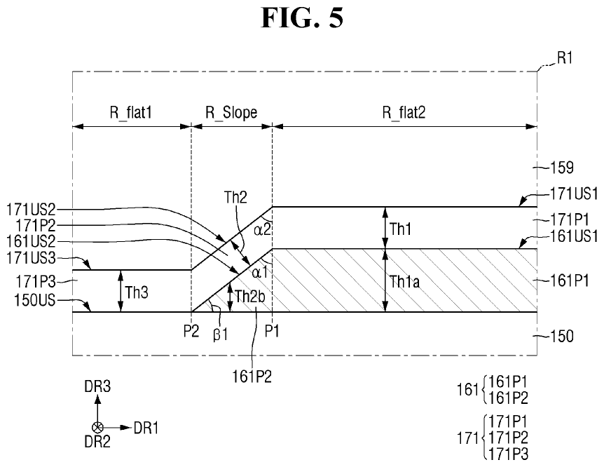

The first enlarged area R1 will be described in detail with reference to FIG. 5 according to an example embodiment.

Referring to FIG. 4 and FIG. 5, the first conductive pattern 161 includes a portion of a flat area R_flat2 that is formed so as to have a uniform first thickness Th1a from the passivation layer 150 in the third direction DR3.

Further, the first conductive pattern 161 includes an inclined area R_Slope. A thickness of the first conductive pattern 161 in the inclined area R_Slope from the passivation layer 150 in the third direction DR3 decreases from a first thickness Th1a as the first conductive pattern 161 extends away from the flat area R_flat2 in the first direction DR1.

In the flat area R_flat2, the first conductive pattern 161 may include a first conductive portion 161P1. The first conductive portion 161P1 may include a first conductive top face 161US1.

In the inclined area R_Slope, the first conductive pattern 161 may include a second conductive portion 161P2. The second conductive portion 161P2 may be connected to the first conductive portion 161P1. The second conductive portion 161P2 may include a second conductive top face 161US2.

That is, the thickness (for example, a thickness Th2b) of the portion of the first conductive pattern 161 in the inclined area R_Slope from the passivation layer 150 in the third direction DR3 has a smaller value than that of the first thickness Th1a. Specifically, the thickness of the inclined area R_Slope of the first conductive pattern 161 may decrease as the inclined area R_Slope of the first conductive pattern 161 extends away from the flat area R_flat2 in the first direction DR1. A height of the second conductive top face 161US2 based on the passivation layer 150 may gradually become smaller from a height of the first conductive top face 161US1 based on the passivation layer 150 as the second conductive top face 161US2 extends away from the first conductive portion 161P1.

The second conductive top face 161US2 may have an inclined shape. The second conductive top face 161US2 may extend in an inclined manner from the first conductive top face 161US1 toward a top face of the passivation layer 150US. For example, the second conductive top face 161US2 may have a first intersection angle β1 relative to the top face of the passivation layer 150US. The second conductive top face 161US2 may intersect with the top face of the passivation layer 150US at the first intersection angle β1. The second conductive top face 161US2 may have a constant slope of the first intersection angle β1 relative to the top face of the passivation layer 150US. The first intersection angle β1 may be greater than 0 degree and smaller than 90 degrees. The second conductive top face 161US2 may be flat.

In other words, a point where the flat area R_flat2 and the inclined area R_Slope meet each other may be defined as a first point P1. That is, a boundary where the flat area R_flat2 and the inclined area R_Slope meet each other extends from the first point P1 in the third direction DR3.

In this regard, the portion of the first conductive pattern 161 in the inclined area R_Slope may have an inclined shape with a slope of a first angle α1 relative to the boundary where the flat area R_flat2 and the inclined area R_Slope meet each other.

The first angle α1 may refer to an angle defined between the third direction DR3 and the second conductive top face 161US2. The first angle α1 may include an inclination of the second conductive top face 161US2 with respect to the third direction DR3. That is, the second conductive portion 161P2 may be inclined at the first angle α1 with respect to the third direction DR3. The first angle α1 may be greater than 0 degree and smaller than 90 degrees.

Thus, the step coverage of the adhesive layer 171 formed on the first conductive pattern 161 may be improved.

That is, vertical dimensions Th1, Th2, and Th3 of the adhesive layer 171 formed on the first conductive pattern 161 from the first conductive pattern 161 in a direction perpendicular to the first conductive pattern 161 may be equal to each other. However, the disclosure is not limited thereto, and the vertical dimensions Th1, Th2, and Th3 of the adhesive layer 171 formed on the first conductive pattern 161 from the first conductive pattern 161 in the direction perpendicular to the first conductive pattern 161 may be different from each other. However, in the inclined area R_Slope, the adhesive layer 171 may be conformally formed on the first conductive pattern 161, so that the adhesive layer 171 is not exposed, thereby improving the step coverage thereof.

The adhesive layer 171 may extend along the passivation layer 150 and the first conductive pattern 161. The adhesive layer 171 may include a first extension 171P1, a second extension 171P3, and a bent portion 171P2.

The first extension 171P1 may extend in the first direction DR1. The first extension 171P1 may be disposed on the first conductive portion 161P1. The first extension 171P1 may extend along the first conductive portion 161P1.

The second extension 171P3 may extend in the first direction DR1. The second extension 171P3 may be disposed on the passivation layer 150. The second extension 171P3 may extend along the passivation layer 150.

The bent portion 171P2 may be disposed on the second conductive portion 161P2. The bent portion 171P2 may extend along the second conductive portion 161P2. The bent portion 171P2 may be disposed between the first extension 171P1 and the second extension 171P3. The bent portion 171P2 may be connected to the first extension 171P1 and the second extension 171P3. The bent portion 171P2 may be bent from the first extension 171P1 and the second extension 171P3. The bent portion 171P2 may have a constant slope with respect to the first extension 171P1. The bent portion 171P2 may have a constant slope with respect to the second extension 171P3.

The bent portion 171P2 may extend in a direction intersecting the first direction DR1. For example, bent portion 171P2 may extend in a direction intersecting the first direction DR1 and the third direction DR3.

The bent portion 171P2 may extend from the boundary where the flat area R_flat2 and the inclined area R_Slope meet each other at an inclination of a second angle α2. The second angle α2 may refer to an angle defined between the third direction DR3 and a top face 171US2 of the bent portion. The second angle α2 may include an angle at which the top face 171US2 of the bent portion is inclined with respect to the third direction DR3. That is, bent portion 171P2 may be inclined at the second angle α2 with respect to the third direction DR3. The second angle α2 may be greater than 0 degree and smaller than 90 degrees.

The second angle α2 may be equal to the first angle α1. However, an embodiment is not limited thereto. For example, the second angle α2 may be different from the first angle α1.

In a cross-sectional view perpendicular to the second direction DR2, the bent portion 171P2 may have an inclined shape. For example, the bent portion 171P2 may have the first intersection angle β1 relative to the top face of the passivation layer 150US. The bent portion 171P2 may be inclined at the first intersection angle β1 with respect to the passivation layer 150. The first intersection angle β1 may be greater than 0 degree and smaller than 90 degrees.

The first extension 171P1 may have a first top face 171US1. The bent portion 171P2 may have a second top face 171US2. The second extension 171P3 may have a third top face 171US3.

A height of the first top face 171US1 and a height of the third top face 171US3 based on the top face of the passivation layer 150US may be different from each other. For example, the third top face 171US3 may be positioned at a higher vertical level than that of the first top face 171US1, based on the top face of the passivation layer 150US.

The second top face 171US2 may be flat. The second top face 171US2 may be inclined relative to the first top face 171US1 and the third top face 171US3. For example, the second top face 171US2 may have an angle greater than 90 degrees and smaller than 180 degrees relative to the first top face 171US1. Alternatively, the second top face 171US2 may intersect the first top face 171US1 at an angle greater than 0 degree but smaller than 90 degrees. The second top face 171US2 may intersect the first top face 171US1 at a non-right angle.

The second top face 171US2 may have an angle greater than 90 degrees and smaller than 180 degrees relative to the third top face 171US3. Alternatively, the second top face 171US2 may intersect the third top face 171US3 at an angle greater than 0 degrees but smaller than 90 degrees. The second top face 171US2 may intersect the third top face 171US3 at a non-right angle.

The second top face 171US2 may extend from a boundary where the flat area R_flat2 and the inclined area R_Slope meet each other at a slope of the second angle α2. The second top face 171US2 may have a slope of the second angle α2 with respect to the third direction DR3.

A thickness of the adhesive layer 171 may be constant. The first extension 171P1 may have a first thickness Th1. The first thickness Th1 may refer to a distance between the first conductive top face 161US1 and the first top face 171US1. The bent portion 171P2 may have a second thickness Th2. The second thickness Th2 may refer to a distance between the second conductive top face 161US2 and the second top face 171US2. The second extension 171P3 may have a third thickness Th3. The third thickness Th3 may refer to a distance between the top face of the passivation layer 150US and the third top face 171US3. The first thickness Th1, the second thickness Th2 and the third thickness Th3 may be equal to each other. However, an embodiment is not limited thereto. For example, the first thickness Th1, the second thickness Th2, and the third thickness Th3 may be different from each other.

Since the second conductive top face 161US2 of the first conductive pattern 161 has the inclined shape, the bent portion 171P2 may conformally extend along and on the first conductive pattern 161. The first extension 171P1 and the second extension 171P3 of the adhesive layer 171 may not be disconnected from each other, but may be stably connected to each other via the bent portion 171P2.

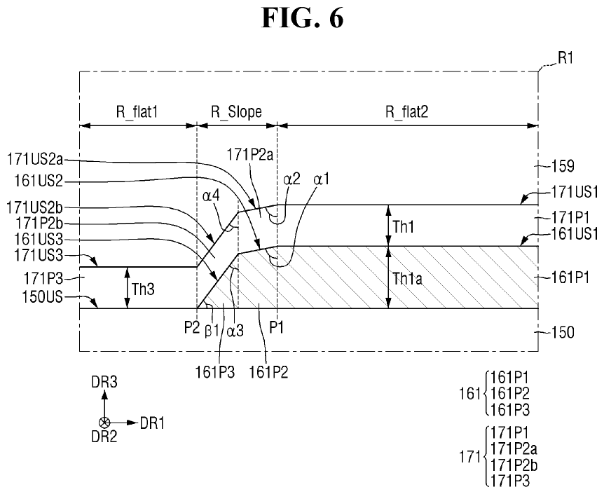

FIG. 6 is a diagram for illustrating an image sensor according to another embodiment of the present disclosure. For convenience of description, differences thereof from the descriptions as set forth above with reference to FIGS. 4 and 5 will be set forth below.

Referring to FIG. 6, in the inclined area R_Slope, the first conductive pattern 161 may include the second conductive portion 161P2 and a third conductive portion 161P3. As the first conductive pattern 161 extends away from the flat area R_flat2, a thickness of the first conductive pattern 161 in the inclined area R_Slope may decrease. The thickness of the first conductive pattern 161 based on the top face of the passivation layer 150US may gradually decrease from the thickness Th1a of the first conductive portion 161P1 as the first conductive pattern 161 extends away from the first conductive portion 161P1 in the first direction DR1.

The second conductive portion 161P2 may have the second conductive top face 161US2. The third conductive portion 161P3 may have a third conductive top face 161US3.

The second conductive top face 161US2 may have a constant slope with respect to the first conductive top face 161US1. The second conductive top face 161US2 may be bent from the first conductive top face 161US1. For example, the second conductive top face 161US2 may have a slope of the first angle α1 with respect to the third direction DR3. The first angle α1 may be greater than 0 degree and smaller than 90 degrees. The second conductive top face 161US2 may include a flat face.

The third conductive top face 161US3 may have a constant slope with respect to the top face of the passivation layer 150US. The third conductive top face 161US3 may be bent from the top face of the passivation layer 150US. The third conductive top face 161US3 may have the first intersection angle β1 relative to the top face of the passivation layer 150US. The third conductive top face 161US3 may extend at a constant slope of the first intersection angle β1 with respect to the first direction DR1. The third conductive top face 161US3 may intersect the top face of the passivation layer 150US at the first intersection angle β1. The first intersection angle β1 may be greater than 0 degree and smaller than 90 degrees.

The third conductive top face 161US3 may be bent from the second conductive top face 161US2. For example, the third conductive top face 161US3 may have a slope of a third angle α3 with respect to the third direction DR3. The third angle α3 may be greater than 0 degree and smaller than 90 degrees. The third conductive top face 161US3 may include a flat face.

In the inclined area R_Slope, the adhesive layer 171 may include a first bent portion 171P2a and a second bent portion 171P2b.

The first bent portion 171P2a may be disposed on the second conductive portion 161P2. The first bent portion 171P2a may extend along the second conductive portion 161P2. The first bent portion 171P2a may be bent from the first extension 171P1. The first bent portion 171P2a may be disposed between the first extension 171P1 and the second bent portion 171P2b. The first bent portion 171P2a may have a constant slope with respect to the first extension 171P1. For example, the first bent portion 171P2a may be inclined at the second angle α2 with respect to the third direction DR3. The second angle α2 may be greater than 0 degree and smaller than 90 degrees. The second angle α2 may be equal to the first angle α1. However, an embodiment is not limited thereto. For example, the second angle α2 may be different from the first angle α1.

The second bent portion 171P2b may be disposed on the third conductive portion 161P3. The second bent portion 171P2b may extend along the third conductive portion 161P3. The second bent portion 171P2b may be bent from the second extension 171P3. The second bent portion 171P2b may be disposed between the second extension 171P3 and the first bent portion 171P2a. The second bent portion 171P2b may have a constant slope with respect to the second extension 171P3. For example, the second bent portion 171P2b may be inclined at a fourth angle α4 with respect to the third direction DR3. The fourth angle α4 may be greater than 0 degree and smaller than 90 degrees. The fourth angle α4 may be equal to the third angle α3. However, an embodiment is not limited thereto. For example, the fourth angle α4 may be different from the third angle α3.

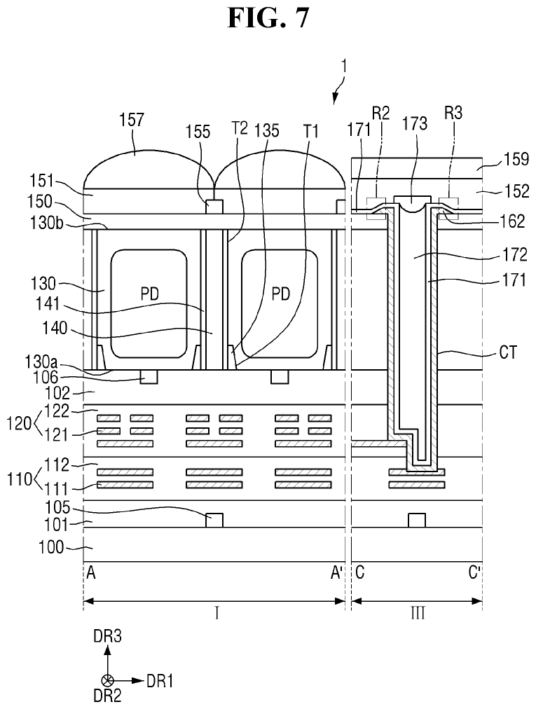

FIG. 7 is a cross-sectional view taken along lines A-A′ and C-C′ in FIG. 3. For reference, in descriptions regarding FIG. 7, contents duplicate with those as described above with reference to FIG. 4 are omitted, and following descriptions are focused on differences therebetween.

Referring to FIG. 7, following description is based on the third area III. The third area III includes a second conductive pattern 162, a low refractive index layer 172, and a photoresist 173.

For convenience of description, the second substrate 130 is defined as including the third area III as a connection area to connect active pixel sensor areas to each other. However, the photoelectric conversion element PD is not provided inside the third area III of the second substrate 130.

Referring to FIG. 7, the second conductive pattern 162 may extend through a portion of the interlayer insulating film 112 and be electrically connected to the wiring layer 111. That is, the second conductive pattern 162 may extend through the wiring structure 120, the insulating layer 102, the substrate 130, and the passivation layer 150 and extend in the third direction DR3.

A connection trench CT may be formed in the third area III of the second substrate 130. The connection trench CT may extend through the passivation layer 150, the second substrate 130, the second insulating layer 102, and the second wiring structure 120 in the third direction DR3. The connection trench CT may extend into the first wiring structure 110.

The connection trench CT may extend into the first wiring layer 111. The connection trench CT may expose at least a portion of the second wiring layer 121. A bottom face of the connection trench CT may have a step.

The second conductive pattern 162 may be provided along a sidewall and a bottom face of the connection trench CT. The second conductive pattern 162 may be formed, for example, conformally. At least a portion of the second conductive pattern 162 may extend onto a top face of the passivation layer 150.

The second conductive pattern 162 may include a metal. For example, the first conductive pattern 161 may include at least one of titanium (Ti) or tungsten (W). However, the disclosure is not limited thereto, and as such, according to another example embodiment, the first conductive pattern 161 may include one or more other materials, or a combination thereof.

According to an embodiment, the low refractive index layer 172 may be provided on the adhesive layer 171 and in the connection trench CT. The low refractive index layer 172 may fill the connection trench CT. The low refractive index layer 172 may include, for example, at least one of an oxide, a nitride, or an oxynitride. However, the disclosure is not limited thereto, and as such, according to another example embodiment, the low refractive index layer 172 may include one or more other materials.

The photoresist 173 may be provided on the low refractive index layer 172. A portion of the photoresist 173 may be provided to protrude from a top face of the adhesive layer 171. However, the disclosure is not limited thereto, and as such, according to another example embodiment, the photoresist 173 may be omitted.

The second color filter 152 may be provided on the second area II of the second substrate 130 as the optical black sensor area and on the third area III of the second substrate 130 as the connection area. The second color filter 152 may be provided on the adhesive layer 171.

The second color filter 152 may be in contact with, for example, a top face of the adhesive layer 171. For example, a vertical level of a top face of the second color filter 152 may be higher than that of a top face of the first color filter 151. However, the disclosure is not limited thereto, and as such, according to another example embodiment, the vertical level of the top face of the second color filter 152 may not be higher than that of the top face of the first color filter 151. The second color filter 152 may include, for example, a blue color filter.

The transparent layer 159 may be provided on the adhesive layer 171 and the second color filter 152. According to an example embodiment, the transparent layer 159 may be provided to on an entirety of the second color filter 152. The transparent layer 159 may be provided to cover, for example, an entirety of the second color filter 152. However, the disclosure is not limited thereto, and as such, according to another example embodiment, the transparent layer 159 may be provided to cover at least a portion of the second color filter 152.

The second conductive pattern 162 extends in the first direction DR1 and includes a portion formed on the passivation layer 150.

The adhesive layer 171 may be formed on the second conductive pattern 162 and conformally formed along the second conductive pattern 162.

Further, the adhesive layer 171 extends in the first direction DR1 and includes a portion formed on the passivation layer 150.

In this regard, the second conductive pattern 162 is deposited on the passivation layer 150 and then subjected to an etching process. In this regard, the second conductive pattern 162 is etched in an inclined manner so as to have an inclined shape as in a second enlarged area R2 and a third enlarged area R3.

Thus, the step coverage of the adhesive layer 171 formed on the second conductive pattern 162 may be improved.

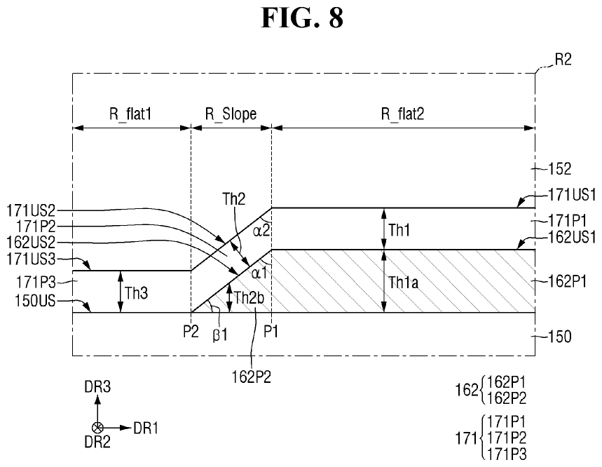

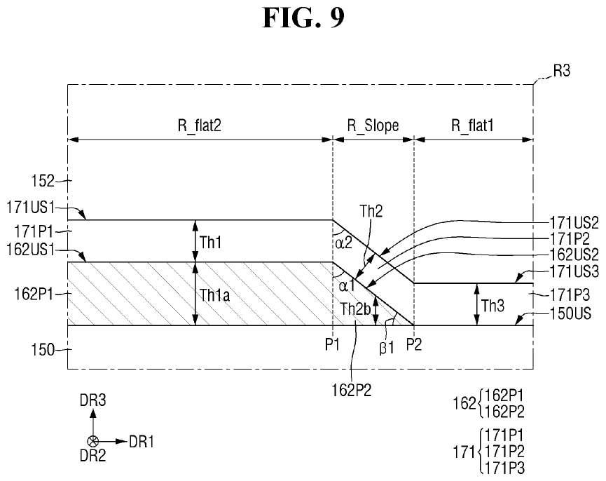

This will be described at in detail with reference to FIG. 8 and FIG. 9.

FIG. 8 is an enlarged view of the R2 area of FIG. 7. FIG. 9 is an enlarged view of the R3 area of FIG. 7.

For reference, because the R3 area of FIG. 9 has a symmetrical shape with respect to the R2 area of FIG. 8, following description may be applied to both the R2 area and the R3 area.

Referring to FIG. 7 to FIG. 9, the second conductive pattern 162 includes a portion of a flat area R_flat2 that is formed so as to have a uniform first thickness Th1a from the passivation layer 150 in the third direction DR3.

Further, the second conductive pattern 162 includes the inclined area R_Slope. A thickness of the second conductive pattern 162 in the inclined area R_Slope from the passivation layer 150 in the third direction DR3 decreases from the first thickness Th1a as the second conductive pattern 162 extends away from the flat area R_flat2 in the first direction DR1.

That is, the thickness (for example, a thickness Th2b) of the portion of the second conductive pattern 162 in the inclined area R_Slope from the passivation layer 150 in the third direction DR3 has a smaller value than that of the first thickness Th1a.

In the flat area R_flat2, the second conductive pattern 162 may include a fourth conductive portion 162P1. The fourth conductive portion 162P1 may include a fourth conductive top face 162US1.

In the inclined area R_Slope, the second conductive pattern 162 may include a fifth conductive portion 162P2. The fifth conductive portion 162P2 may be connected to the fourth conductive portion 162P1. The fifth conductive portion 162P2 may include a fifth conductive top face 162US2.

A thickness of the second conductive pattern 162 in the inclined area R_Slope may decrease as the second conductive pattern 162 extends away from the flat area R_flat2 in the first direction DR1. A height of the fifth conductive top face 162US2 based on the passivation layer 150 may gradually become smaller from a height of the fourth conductive top face 162US1 based on the passivation layer 150 as the fifth conductive top face 162US2 extends away from the fourth conductive portion 162P1.

In other words, a point where the flat area R_flat2 and the inclined area R_Slope meet each other may be defined as a first point P1. That is, a boundary where the flat area R_flat2 and the inclined area R_Slope meet each other extends from the first point P1 in the third direction DR3.

In this regard, the portion of the second conductive pattern 162 in the inclined area R_Slope may have an inclined shape with a slope of a first angle α1 relative to the boundary where the flat area R_flat2 and the inclined area R_Slope meet each other.

The first angle α1 may refer to an angle defined between the third direction DR3 and the fifth conductive top face 162US2. The first angle α1 may include an angle at which the fifth conductive top face 162US2 is inclined with respect to the third direction DR3. That is, the fifth conductive portion 162P2 may be inclined at the first angle α1 with respect to the third direction DR3. The first angle α1 may be greater than 0 degree and smaller than 90 degrees.

The fifth conductive top face 162US2 may have an inclined shape. The fifth conductive top face 162US2 may extend from the fourth conductive top face 162US1 to the top face of the passivation layer 150US in an inclined manner. For example, the fifth conductive top face 162US2 may have the first intersection angle β1 relative to the top face of the passivation layer 150US. The fifth conductive top face 162US2 may intersect the top face of the passivation layer 150USefirst intersection angle β1. The fifth conductive top face 162US2 may have a constant slope of the first intersection angle β1 with respect to the top face of the passivation layer 150USefirst intersection angle β1 may be greater than 0 degree and smaller than 90 degrees. The fifth conductive top face 162US2 may include a flat face.

Thus, the step coverage of the adhesive layer 171 formed on the second conductive pattern 162 may be improved.

In the inclined area R_Slope, the adhesive layer 171 may be conformally formed on the second conductive pattern 162, so that the adhesive layer 171 is not exposed, thereby improving the step coverage thereof.

The adhesive layer 171 may extend along the passivation layer 150 and the second conductive pattern 162. The adhesive layer 171 may include the first extension 171P1, the second extension 171P3, and the bent portion 171P2.

The bent portion 171P2 may be disposed on the fifth conductive portion 162P2. The bent portion 171P2 may extend along the fifth conductive portion 162P2. The bent portion 171P2 may be disposed between the first extension 171P1 and the second extension 171P3. The bent portion 171P2 may be connected to the first extension 171P1 and the second extension 171P3. The bent portion 171P2 may be bent from the first extension 171P1 and the second extension 171P3. The bent portion 171P2 may have a constant slope with respect to the first extension 171P1. The bent portion 171P2 may have a constant slope with respect to the second extension 171P3.

The bent portion 171P2 may extend from the boundary where the flat area R_flat2 and the inclined area R_Slope meet each other at a slope of the second angle α2. The second angle α2 may refer to an angle defined between the third direction DR3 and the top face of the bent portion 171US2. The second angle α2 may include an angle at which the top face of the bent portion 171US2 is inclined with respect to the third direction DR3. That is, the bent portion 171P2 may be inclined at the second angle α2 with respect to the third direction DR3. The second angle α2 may be greater than 0 degree and smaller than 90 degrees. The second angle α2 may be equal to the first angle α1. However, an embodiment is not limited thereto. For example, the second angle α2 may be different from the first angle α1.

In a cross-sectional view perpendicular to the second direction DR2, the bent portion 171P2 may have an inclined shape. For example, the bent portion 171P2 may have the first intersection angle β1 relative to the top face of the passivation layer 150US. The bent portion 171P2 may be inclined at the first intersection angle β1 with respect to the passivation layer 150. The first intersection angle β1 may be greater than 0 degree and smaller than 90 degrees.

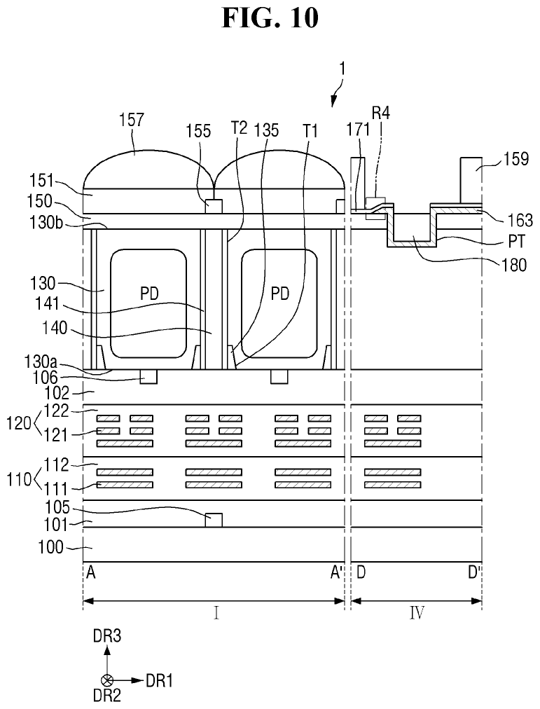

FIG. 10 is a cross-sectional view taken along lines A-A′ and D-D′ in FIG. 3.

For reference, in descriptions about FIG. 10, contents duplicate with those as described above with reference to FIG. 4 and FIG. 7 are omitted, and following description is focused on differences therebetween.

Referring to FIG. 10, the fourth area IV includes a third conductive pattern 163 and the pad 180.

For convenience of description, the second substrate 130 is defined as including the fourth area IV as the pad area. However, the photoelectric conversion element PD is not provided inside the fourth area IV of the second substrate 130.

A pad trench PT may be formed in the fourth area IV of the second substrate 130 as the pad area. The pad trench PT may extend through the passivation layer 150 in the third direction DR3 and extend into the second substrate 130.

The third conductive pattern 163 may be provided along a sidewall and a bottom face of the pad trench PT. The third conductive pattern 163 may be formed, for example, conformally. At least a portion of the third conductive pattern 163 may extend onto the top face of the passivation layer 150.

The third conductive pattern 163 may include a metal. For example, the third conductive pattern 163 may include at least one of titanium (Ti) or tungsten (W). However, the disclosure is not limited thereto, and as such, according to another example embodiment, the third conductive pattern 163 may include one or more other materials, or a combination thereof.

The first color filter 151 as described above with reference to FIG. 10 is not provided on the fourth area IV of the second substrate 130 as the pad area.

The transparent layer 159 as described above with reference to FIG. 10 is not provided on the pad 180. The transparent layer 159 may include, for example, a material that transmits light therethrough.

The pad 180 may fill the pad trench PT and may be provided on the third conductive pattern 163. The pad 180 may include a conductive material.

The adhesive layer 171 may not vertically overlap the pad 180. The adhesive layer 171 may not be disposed in the pad trench PT.

In this regard, the third conductive pattern 163 is deposited on the passivation layer 150 and then subjected to an etching process. In this regard, the third conductive pattern 163 is etched in an inclined manner so as to have an inclined shape as in a fourth enlarged area R4.

Thus, the step coverage of the adhesive layer 171 formed on the third conductive pattern 163 may be improved.

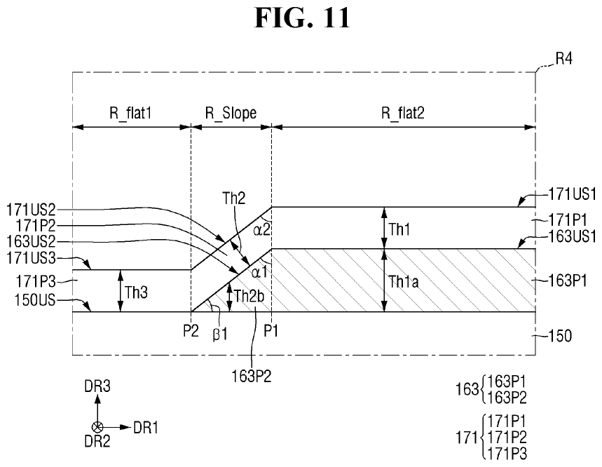

This will be described at in detail with reference to FIG. 11.

FIG. 11 is an enlarged view of the R4 area of FIG. 10.

Referring to FIG. 10 and FIG. 11, the third conductive pattern 163 includes a portion of a flat area R_flat2 that is formed so as to have a uniform first thickness Th1a from passivation layer 150 in the third direction DR3.

Further, the third conductive pattern 163 includes a portion of an inclined area R_Slope in which a thickness thereof from passivation layer 150 in the third direction DR3 decreases from the first thickness Th1a as the portion of the pattern 161 extends along an opposite direction to the first direction DR1.

That is, the thickness (for example, a thickness Th2b) of the portion of the third conductive pattern 163 in the inclined area R_Slope from the passivation layer 150 in the third direction DR3 has a smaller value than that of the first thickness Th1a.

In the flat area R_flat2, the third conductive pattern 163 may include a sixth conductive portion 163P1. The sixth conductive portion 163P1 may include a sixth conductive top face 163US1.

In the inclined area R_Slope, the third conductive pattern 163 may include a seventh conductive portion 163P2. The seventh conductive portion 163P2 may be connected to the sixth conductive portion 163P1. The seventh conductive portion 163P2 may include a seventh conductive top face 163US2.

A thickness of the third conductive pattern 163 in the inclined area R_Slope may decrease as the third conductive pattern 163 extends away from the flat area R_flat2 in the first direction DR1. A height of the seventh conductive top face 163US2 based on the passivation layer 150 may gradually become smaller from a height of the sixth conductive top face 163US1 based on the passivation layer 150 as the seventh conductive top face 163US2 extends away from the sixth conductive portion 163P1.

In other words, a point where the flat area R_flat2 and the inclined area R_Slope meet each other may be defined as a first point P1. That is, a boundary where the flat area R_flat2 and the inclined area R_Slope meet each other extends from the first point P1 in the third direction DR3.

In this regard, the portion of the third conductive pattern 163 in the inclined area R_Slope may have an inclined shape with a slope of a first angle α1 relative to the boundary where the flat area R_flat2 and the inclined area R_Slope meet each other. Thus, the step coverage of the adhesive layer 171 formed on the third conductive pattern 163 may be improved.

The first angle α1 may refer to an angle defined between the third direction DR3 and the seventh conductive top face 163US2. The first angle α1 may include an angle at which the seventh conductive top face 163US2 is inclined with respect to the third direction DR3. That is, the seventh conductive portion 163P2 may be inclined at the first angle α1 with respect to the third direction DR3. The first angle α1 may be greater than 0 degree and smaller than 90 degrees.

The seventh conductive top face 163US2 may have an inclined shape. The seventh conductive top face 163US2 may extend from the sixth conductive top face 162US1 to the top face of the passivation layer 150USefirst intersection angle β1 relative to the top face of the passivation layer 150US. The seventh conductive top face 163US2 may intersect the top face of the passivation layer 150US at the first intersection angle β1. The seventh conductive top face 163US2 may have a constant slope of the first intersection angle β1 with respect to the top face of the passivation layer 150US. The first intersection angle β1 may be greater than 0 degree and smaller than 90 degrees. The seventh conductive top face 163US2 may include a flat face.

In the inclined area R_Slope, the adhesive layer 171 may be conformally formed on the third conductive pattern 163, so that the adhesive layer 171 is not exposed, thereby improving the step coverage thereof.

The adhesive layer 171 may extend along the passivation layer 150 and the third conductive pattern 163. The adhesive layer 171 may include the first extension 171P1, the second extension 171P3, and the bent portion 171P2.

The bent portion 171P2 may be disposed on the seventh conductive portion 163P2. The bent portion 171P2 may extend along the seventh conductive portion 163P2. The bent portion 171P2 may be disposed between the first extension 171P1 and the second extension 171P3. The bent portion 171P2 may be connected to the first extension 171P1 and the second extension 171P3. The bent portion 171P2 may be bent from the first extension 171P1 and the second extension 171P3. The bent portion 171P2 may have a constant slope with respect to the first extension 171P1. The bent portion 171P2 may have a constant slope with respect to the second extension 171P3.

For example, the bent portion 171P2 may extend in a direction intersecting the first direction DR1 and the third direction DR3.

The bent portion 171P2 may extend from the boundary where the flat area R_flat2 and the inclined area R_Slope meet each other in an inclined manner of the second angle α2. The second angle α2 may refer to an angle defined between the third direction DR3 and the top face of the bent portion 171US2. The second angle α2 may include an angle at which the top face of the bent portion 171US2 is inclined with respect to the third direction DR3. That is, the bent portion 171P2 may be inclined at the second angle α2 with respect to the third direction DR3. The second angle α2 may be greater than 0 degree and smaller than 90 degrees. The second angle α2 may be equal to the first angle α1. However, an embodiment is not limited thereto. For example, the second angle α2 may be different from the first angle α1.

In a cross-sectional view perpendicular to the second direction DR2, the bent portion 171P2 may have an inclined shape. For example, the bent portion 171P2 may have the first intersection angle β1 relative to the top face of the passivation layer 150US. The bent portion 171P2 may be inclined at the first intersection angle β1 with respect to the passivation layer 150. The first intersection angle β1 may be greater than 0 degree and smaller than 90 degrees.

Although embodiments of the disclosure have been described above with reference to the accompanying drawings, it will be understood by those of ordinary skill in the art that the disclosure is not limited thereto and may be implemented in many different forms without departing from the technical idea or features thereof. Therefore, it should be understood that the embodiments set forth herein are merely examples in all respects and not restrictive.

What is claimed is:

1. An image sensor comprising:
a substrate having a photoelectric conversion element disposed therein;
a passivation layer disposed on the substrate and extending in a first direction;
a conductive pattern disposed on the passivation layer; and
an adhesive layer deposited on the passivation layer and the conductive pattern,
wherein the conductive pattern includes:
a first flat area disposed on the passivation layer and extending in the first direction; and
an inclined area connected to the first flat area,
wherein a first top face of the inclined area is bent from a second top face of the first flat area,
wherein the first top face has a constant slope with respect to the second top face.

2. The image sensor of claim 1, wherein the first top face has a slope of a first angle with respect to a second direction perpendicular to the first direction,
wherein the first angle is greater than 0 degree and smaller than 90 degrees.

3. The image sensor of claim 1, wherein the adhesive layer includes:
a first portion extending along the second top face of the first flat area; and
a second portion extending along the first top face of the inclined area,
wherein a third top face of the second portion has a constant slope with respect to a fourth top face of the first portion.

4. The image sensor of claim 3, wherein the third top face has a slope of a second angle with respect to a second direction perpendicular to the first direction,
wherein the second angle is greater than 0 degree and smaller than 90 degrees.

5. The image sensor of claim 3, wherein the first top face has a slope of a first angle with respect to a second direction perpendicular to the first direction,
wherein the third top face has a slope of a second angle relative to the second direction,
wherein the first angle and the second angle are equal to each other.

6. The image sensor of claim 3, wherein the adhesive layer further includes a third portion connected to the second portion and directly contacting a top face of the passivation layer,
wherein the third top face has a constant slope with respect to a fifth top face of the third portion.

7. The image sensor of claim 3, wherein a first thickness of the first portion based on the second top face is equal to a second thickness of the second portion based on the first top face.

8. The image sensor of claim 1, wherein the first top face intersects a top face of the passivation layer.

9. An image sensor comprising:
a substrate having a photoelectric conversion element disposed therein;
a passivation layer disposed on the substrate and extending in a first direction;
a conductive pattern formed on the passivation layer; and
an adhesive layer formed along the conductive pattern and formed on the passivation layer,
wherein the conductive pattern includes:
a first flat area extending from the passivation layer in a second direction perpendicular to the first direction and extending so as to have a first constant thickness;
an inclined area, wherein a thickness of the conductive pattern in the inclined area from the passivation layer in the second direction decreases from the first thickness as the conductive pattern in the inclined area extends away from the first flat area in the first direction.

10. The image sensor of claim 9, wherein the inclined area of the conductive pattern includes:
a first portion adjacent to the first flat area; and
a second portion adjacent to the first portion and spaced apart from the first flat area while the first portion is interposed between the second portion and the first flat area,
wherein a first top face of the first portion is bent from a top face of the first flat area,
wherein a second top face of the second portion is bent from the first top face so as to be connected to the top face of the passivation layer,
wherein the first top face has a first slope with respect to the top face of the first flat area,
wherein the second top face has a second slope with respect to the top face of the passivation layer, wherein the second slope is different from the first slope.

11. The image sensor of claim 10, wherein the first top face has a slope of a first angle relative to the second direction,
wherein the second top face has a slope of a second angle relative to the second direction,
wherein each of the first angle and the second angle is greater than 0 degree and smaller than 90 degrees.

12. The image sensor of claim 9, wherein a third top face of the inclined area has a slope greater than 0 degree and smaller than 90 degrees with respect to the top face of the passivation layer, and intersects the top face of the passivation layer.

13. The image sensor of claim 9, wherein the adhesive layer includes:
a first extension extending in the first direction and along the top face of the passivation layer;
a bent portion disposed on the inclined area of the conductive pattern and extending along the conductive pattern, wherein the bent portion is bent from the first extension; and
a second extension disposed on the first flat area of the conductive pattern and extending in the first direction,
wherein the bent portion has a constant slope relative to each of the first extension and the second extension.

14. The image sensor of claim 13, wherein a top face of the bent portion is flat.

15. The image sensor of claim 9, wherein a top face of the inclined area is flat.

16. The image sensor of claim 9, further comprising:
an insulating layer disposed under the substrate;
a trench extending through the insulating layer, the substrate, and the passivation layer, wherein each of the conductive pattern and the adhesive layer extends along a profile of the trench; and
a low refractive index layer filling an entirety of the trench so as to be surrounded with the adhesive layer; and
a photoresist disposed on a top face of the low refractive index layer.

17. An image sensor comprising:
a substrate:
a passivation layer disposed on the substrate and extending in a first direction;
a trench extending through the passivation layer and extending through a portion of the substrate;
a conductive pattern extending along a profile of the trench and formed on the passivation layer;
a pad disposed in the trench and on the conductive pattern; and
an adhesive layer formed on the conductive pattern and the passivation layer,
wherein the conductive pattern includes:
a first flat area disposed on the passivation layer and extending in the first direction; and
an inclined area connected to the first flat area, wherein a top face of the conductive pattern in the inclined area is inclined at a first slope of a first angle relative to a top face of the passivation layer,
wherein the first angle is greater than 0 degree and smaller than 90 degrees,
wherein a top face of the conductive pattern in the inclined area is flat.

18. The image sensor of claim 17, wherein the adhesive layer non-overlaps the pad.

19. The image sensor of claim 17, wherein the adhesive layer includes:
a first extension extending along the top face of the passivation layer and in the first direction and;
a bent portion disposed on the inclined area of the conductive pattern and extending along the conductive pattern, wherein the bent portion is bent from the first extension; and
a second extension disposed on the first flat area of the conductive pattern and extending in the first direction, wherein the second extension is connected to the bent portion,
wherein a top face of the bent portion has a slope of a second angle with respect to the top face of the passivation layer,
wherein the second angle is greater than 0 degree and smaller than 90 degrees.

20. The image sensor of claim 19, wherein an end of the conductive pattern including the inclined area is surrounded with the bent portion and the first extension of the adhesive layer.
